(19) United States
(12) Patent Application Publication
(10) Pub. No.: US 2025/0266570 A1
(43) Pub. Date: Aug. 21, 2025

(54) METHODS OF REACTIVE DRYING A SEPARATOR DURING BATTERY MANUFACTURING, DRIED SEPARATORS, AND BATTERIES CONTAINING THE SEPARATOR

(71) Applicant: Forge Nano, Inc., Thornton, CO (US)

(72) Inventors: David M. King, Sudbury, MA (US); Arrelaine Dameron, Boulder, CO (US); Markus Groner, Louisville, CO (US)

(21) Appl. No.: 18/856,487

(22) PCT Filed: Apr. 14, 2023
(86) PCT No.: PCT/US2023/018740

§ 371 Date: Oct. 11, 2024

(51) Int. Cl. H01M 50/403; H01M 50/417; H01M 50/431; H01M 50/449; H01M 50/491

(52) U.S. Cl. CPC H01M 50/403; H01M 50/417; H01M 50/431; H01M 50/449; H01M 50/491

(57) ABSTRACT

Methods and apparatus are described that reduce water during the manufacture of battery cells. A Reactive Drying (RD) manufacturing process is described that is incorporated in a battery manufacturing process. A RD process that is used to scavenge water can also provide beneficial ceramic phases within the electrode or substrate that is being treated. This process can be incorporated into the battery manufacturing process to reduce the amount of water in a finished battery.

### BACKGROUND

Lithium-ion (Li-ion) batteries are constructed using an anode, a cathode, a separator and an electrolyte. Known types of Li-ion battery materials that can intercalate lithium include lithium cobalt oxide, lithium manganese oxide, lithium nickel manganese oxide, lithium iron phosphate, lithium nickel cobalt aluminum oxide and lithium titanate oxide, amongst others. Li-ion batteries sometimes use lithium metal, silicon, silicon alloys, graphite or other carbonaceous materials in the anodes and active materials in the cathode like cobalt, nickel, manganese, iron, aluminum, and titanium. The electrolyte can be based upon a lithium salt, such as LiPF6, and solvents that may be carbonate-based. In operation, lithium ions move from the anode to the cathode through the electrolyte and separator during discharge. The ion movement is reversed when the battery is charged.

One problem with Li-ion batteries is that internal water can be detrimental to their performance and safety. Under electrochemical potential, particularly at higher voltages, residual H2O molecular impurities cause a myriad of direct and indirect problems including: electrolyte decomposition due to catalytic hydrolysis at the cathode leading to CO and CO2 formation and cell ballooning, H2 evolution due to reduction at the cathode leading cell ballooning and to reactive OH-formation, cathodic oxidation leading to interfacial resistance gains, etc. This basically results in a simple corollary: the higher the upper cut-off voltage, the more stringent the moisture and drying requirements. Battery manufacturers equate the down-turn in performance of a conventional ceramic-coated separator as representative of the effect of excess moisture driving eventual cell failure, exacerbated by the extreme conditions demanded by current and future electrification initiatives, including high energy cathode and anode materials, 4.4V and higher top of charge capabilities, and 6C charge rates for fast charging electric vehicles.

One example of the negative effect of residual water in a battery is where LiPF6 combines with water according to the following chemical reaction:

LiPF6+H2O→2HF+LiF+POF3 (1)

This reaction causes several problems with the battery. The reduction of the electrolyte LiPF6 reduces the conductivity of the battery, thus increasing its resistance and reducing its energy and power densities. Furthermore, the creation of HF causes potential problems like the breakdown of the active materials in the cathodes, which causes the release of heat and can potentially lead to separator shrinkage and thermal runaway. Batteries are also typically subjected to a painstaking formation process, which oftentimes is critical in the formation of a surface or solid electrolyte interphase (SEI) film formed on the anode and/or cathode. Retained water may also play a role in the degradation of a beneficial SEI film throughout its lifetime.

The electrodes (anodes and cathodes) undergo thermal drying steps during their manufacture. Separators similarly undergo thermal drying steps, initially upon being produced at their location of manufacture, prior to being fabricated into a battery at the battery manufacturing site, or both. To further minimize the amount of water in the finished batteries, the cells are manufactured in a humidity-controlled environment. Dried anodes and cathodes are combined with separators in the humidity-controlled environment by, for example, stacking, z-folding, prismatic winding, and circular or round winding. Efforts to minimize the amount of water or residual moisture in the finished cells add time and cost to the manufacturing process, however even in humidity-controlled environments, hygroscopic materials typically found on electrodes and ceramic-coated separators adsorb ambient moisture and provide a source of water to finished cells. Thermal drying steps are inefficient and inadequate to further reduce retained water in the cells.

### SUMMARY

The invention provides methods and apparatus to reduce water during the manufacture of battery cells. A Reactive Drying (RD) manufacturing process is described that is incorporated in the battery manufacturing process. A RD process that is used to scavenge water can also provide beneficial ceramic phases within the electrode or substrate that is being treated. This process is incorporated into the battery manufacturing process to reduce the amount of water in the finished battery. RD, chemical drying and Chemical Vapor Drying (CVD) are used interchangeably herein.

In a first aspect, the invention provides a method of drying a porous sheet, comprising: providing a porous sheet comprising a material; the porous sheet having two major surfaces and being defined by three mutually-perpendicular directions of thickness, height and width, wherein thickness is the smallest dimension; wherein the material comprises a moisture content of at least 200 ppm (or at least 250 ppm, or at least 300 ppm, or in the range of 200 to 1000 ppm) as measurable by ASTM D7191-10; the porous sheet comprising: an upper region defined as the cross-sectional area extending from the upper surface to 10% of the thickness of the porous sheet, and along the width of the porous sheet; a middle region defined as the cross-sectional area beginning at a point that is 45% of the thickness of the porous sheet from the upper surface, extending to a distance that is 45% of the thickness of the porous sheet from the lower surface, and along the width of the porous sheet; a lower region defined as the cross-sectional area extending from the lower surface to 10% of the thickness of the porous sheet, and along the width of the porous sheet; exposing the upper region of the porous sheet to a gaseous precursor, wherein the gaseous precursor comprises one or more elements selected from the group consisting of Li, B, C, Na, Mg, Al, Si, K, Ca, Sc, Ti, Zn, Ga, Ge, Sr, Y and Zr, and is reactive with water. The step of exposing is conducted for a limited time and/or with a limited precursor such that the concentration by mass of said one or more elements in the upper region is at least 10% (or at least 20% or in the range of 10 to 70% or 10 to 50%) higher than the concentration of said one or more elements in the middle region and is in the range of 0.01% to 1%, or 0.01 to 0.5%, or 0.01 to 0.1%, or 0.01 to 0.05%.

“Major surfaces” refers to geometric surface (ignoring microscopic surface area); for example, in a sponge cut in the shape of a rectangular prism having dimensions of 1 cm×20 cm×10 cm (thickness×width×height), the two major surfaces each have an area of 200 cm2. “Porous” means having through-porosity in the thickness direction such that a fluid can flow through pores having a pore diameter of at least 10 nm, in some embodiments at least 100 nm. Thickness is preferably in the range of 1 to 10000 μm, or 1 to 1000 μm, or 2 to 500 μm. height is the same as or less than width, and preferably in the range of 0.5 to 200 cm, or 1 to 100 cm; width is not limited and is often the length of a roll or roll-to-roll; in some embodiments in the range of 0.1 to 500 m, or 0.1 to 100 m.

Any of the inventive methods can be further characterized by one or any combination of of the following: wherein the porous sheet is the web in a roll-to-roll system; in such a system, web speed is preferably in the range of 0.1 to 100 m/min, or 0.2 to 60 m/min, or 0.5 to 30 m/min, or 1 to 30 m/min, or 10 to 30 m/min, or 20 to 30 m/min; wherein the RD precursor flow rate is in the range of 5 to 5,000 sccm, or 10 to 1,000 sccm, or 50 to 1,000 sccm, or 100 to 500 sccm; based on a web speed of 10 m/min; wherein the ratio of RD precursor flow rate to measured moisture is preferably in the range of 0.05 to 200 sccm/ppm H2O, or 0.01 to 150 sccm/ppm H2O, or 0.01 to 100 sccm/ppm H2O, or 0.5 to 100 sccm/ppm H2O, or 0.5 to 50 sccm/ppm H2O; wherein the ratio of the measured moisture relative to the delivery of a precursor comprising the one or more elements selected from the group consisting of Li, B, C, Na, Mg, Al, Si, K, Ca, Sc, Ti, Zn, Ga, Ge, Sr, Y and Zr per surface area of substrate article to be treated is in the range of 0.001 to 1, or 0.01 to 1, or 0.05 to 1, or 0.1 to 0.5, in order to produce the concentration of said one or more elements in the middle region in the range of 0.01% to 1%, or 0.01 to 0.5%, or 0.01 to 0.1%, or 0.01 to 0.05%; wherein, following the step of exposing, the moisture content of the porous sheet is 190 ppm or less, or 170 ppm or less, or in the range of 50 to 190 ppm; wherein the material is a carbon-based polymer, preferably polyethylene or polypropylene, or PVDF, PTFE, PLA, or polystyrene; wherein the precursor comprises Al, Ti and/or Si; wherein the material comprising a moisture content of at least 200 ppm has been dried by vacuum or desiccation; wherein, before or after the step of exposing, the porous sheet is not exposed to water or a gas that reacts with the one or more elements.

The invention includes a porous separator made by any of the methods described herein.

The invention also includes a method making a battery comprising, following the step of exposing, stacking the porous sheet as a separator with an anode and a cathode. The invention further includes a battery made by this method.

In a further aspect, the invention provides a porous sheet, comprising: a porous sheet comprising a material; the porous sheet having two major surfaces and being defined by three mutually-perpendicular directions of thickness, height and width, wherein thickness is the smallest dimension; wherein the material comprises a moisture content of 190 ppm or less, or 170 ppm or less, or in the range of 90 to 190 ppm as measurable by ASTM D7191-10; the porous sheet comprising: an upper region defined as the cross-sectional area extending from the upper surface to 10% of the thickness of the porous sheet, and along the width of the porous sheet; a middle region defined as the cross-sectional area beginning at a point that is 45% of the thickness of the porous sheet from the upper surface, extending to a distance that is 45% of the thickness of the porous sheet from the lower surface, and along the width of the porous sheet; a lower region defined as the cross-sectional area extending from the lower surface to 10% of the thickness of the porous sheet, and along the width of the porous sheet; the upper region of the porous sheet comprising one or more elements selected from the group consisting of Zn, Cd, Hg, Al, Ga, In, Si, Ge, Sn and Pb; wherein the concentration by mass of said one or more elements in the upper region is at least 10% (or at least 20% or in the range of 10 to 70% or 10 to 50%) higher than the concentration of said one or more elements in the middle region and is in the range of 0.01% to 1%, or 0.01 to 0.5%, or 0.01 to 0.1%, or 0.01 to 0.05%.

The porous sheet can be further characterized by one or any combination of the following features: wherein the concentration by mass of said one or more elements in the lower region is at least 10% (or at least 20% or in the range of 10 to 70% or 10 to 50%) higher than the concentration of said one or more elements in the middle region; wherein the concentration by mass of said one or more elements in the lower region is at least 10% (or at least 20% or in the range of 10 to 70% or 10 to 50%) lower than the concentration of said one or more elements in the middle region; wherein the one or more elements are selected from the group consisting of Al and Si.

The invention also includes a battery comprising the porous sheet.

The method or porous sheet may be further characterized by ±10% or ±20% or ±30% of any of the properties and/or measurements described herein.

As is standard patent terminology, the term “comprising” means “including” and does not exclude additional components. Any of the inventive aspects described in conjunction with the term “comprising” also include narrower embodiments in which the term “comprising” is replaced by the narrower terms “consisting essentially of” or “consisting of.”

### BRIEF DESCRIPTION OF THE DRAWINGS

FIG. 1A shows the parts of a Li-ion battery;

FIG. 1B shows a prior art ceramic coated separator;

FIG. 2 shows a battery separator coating apparatus;

FIGS. 3A-D show various approaches for one or more Reactive Drying systems operating in-line with a winding apparatus in a roll-to-roll configuration, and various windings and folding of the battery anode, cathode and separator.

FIG. 4 shows the separator of the invention after having received a Reactive Drying treatment, with different regions highlighted, and the z-direction defined as the direction perpendicular from the first surface to the second surface in order to define a penetration depth;

FIGS. 5A-D show average weight loadings of ceramic inclusions in the form of layers that can be formed at different penetration depths within the separator using one or more Reactive Drying systems of the invention.

### DETAILED DESCRIPTION

U.S. Pat. No. 9,376,750 is incorporated herein which describes alumina ALD on separator materials. The present invention is different in that the precursor is not applied evenly over all surfaces. More preferably, after the step of exposing, there is not another exposure with a reactive material (and not a “wetting agent” as described in U.S. Pat. No. 9,376,750); the present invention uses only half of an ALD cycle to dry the material; preferably there is not a full ALD cycle.

The following description describes particulars for reducing the amount of water in a finished battery. In particular, described is an in-line roll-to-roll battery electrode or separator drying step that is used with battery cell manufacturing to leverage the water reactive nature of the drying materials as moisture scavengers to eliminate water contaminants, the leading cause of cell degradation. This will further extend battery lifetime and de-risk implementation of lower cost process intensification steps like water cast electrodes or reduced formation and/or thermal drying procedures.

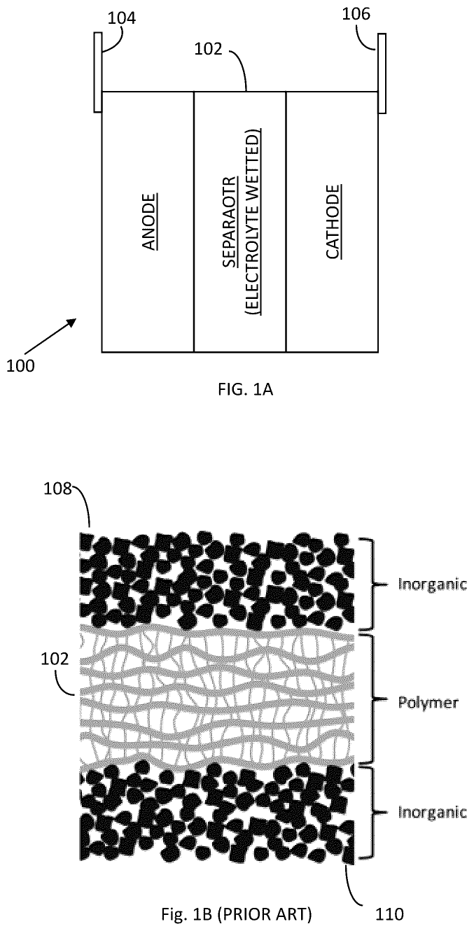

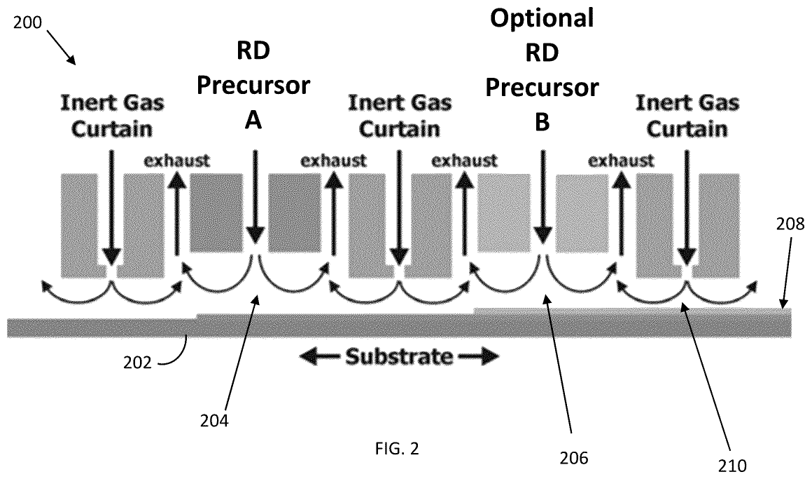

FIG. 1A shows an exemplary, simplified Li-ion battery cell 100. Battery 100 includes an anode, a cathode, a separator wetted with an electrolyte (102), and two current collectors 104, 106 (respectively negative and positive). The anode and cathode store lithium. The electrolyte carries positively charged lithium ions from the anode to the cathode for discharging and vice versa for charging through the separator. The movement of the lithium ions creates free electrons in the anode which creates a charge at the positive current collector 104. The electrical current then flows from the current collector 104 through a device being powered to the negative current collector 106. The separator 102 blocks the flow of electrons inside the battery.

The separator of FIG. 1A can be coated, such as with a layer of ceramic particles applied to the external surface or surfaces of the separator using a liquid-based process as taught by the prior art. FIG. 1B shows such a coated separator having a coating of inorganic particles (108 and 110) applied to each side of separator 102. Conventional separator thicknesses range from 2-50 microns, where batteries designed for higher power applications typically prefer thinner separators, e.g. 2-10 microns, to reduce the distance of ionic pathways. Coated battery separators can then be acquired by battery manufacturers. Liquid-based coating processes for separators rely on uniform application of slurries comprising ceramic particles, and typical coating thicknesses range from 1-10 microns in thickness. Thinner inorganic coating layers are also preferable to reduce the distance of ionic pathways created by the coating layers. In order to minimize the slurry coating thickness while maintaining a uniform layer, smaller particles would be preferable, and bi-modal or trimodal particle size distributions may be best suited to minimize void fraction within the layers. Smaller particles however have higher surface area. In that case the coated separators require additional drying steps due to the hygroscopic nature of the ceramic phase. Thicker ceramic coating layers also create diffusion barriers and can trap water within the separator itself. Analogous concerns are present for electrodes that comprise polymeric binder materials. Separators potentially introduce the majority of the water impurities to batteries fabricated in a dry-room environment.

Polypropylene separators were found to have over 5× the moisture content of LiNiMnCoO2 (NMC) cathode powders. The moisture uptake that occurs during transport, storage and exposure to the battery manufacturing environment can provide at least 300 ppm of moisture uptake, whereas total moisture content below 100 ppm, 50 ppm, or lower, is desirable. Battery manufacturers dry electrodes and separators before using them to make the battery cells. Coated separators tend to incur a larger moisture uptake due to the hygroscopic nature of the coating materials used. Despite best manufacturing practices to maintain a coated separator in a dry state, the coated separator will re-absorb moisture even when only exposed to a dry room environment.

To overcome the moisture problem, one aspect of the present disclosure describes a Reactive Drying (RD) process that can be simultaneously used to apply desirable hygroscopic ceramic materials, such as Al₂O₃, but is integrated in-line with cell formation (stacking, z-folding, prismatic winding, or circular or round winding) where a “chemical drying” effect of the process when applied immediately before the electrodes and separator are physically contacted with one another can minimize the time and opportunity for moisture re-uptake. Additionally, this chemical drying effect can be applied to nearly any surface in the battery manufacturing process (e.g., current collectors, fabricated electrodes, pouch and/or packaging materials, etc.) to reduce total moisture that would otherwise be present in the finished battery, to lower dry room requirements, and to help integrate water-based electrode fabrication processes, and reduce the time and energy consumption of drying steps. Thus, the invention includes methods of drying these components, the treated components, and batteries comprising one or more of the treated components.

Atomic layer deposition (ALD) is a thin-film fabrication process during which vapor phase precursors are separately and sequentially introduced to a surface (including polymeric materials). Each precursor that reacts with the surface changes the surface functionality to a new functionality that will be reactive with the next precursor in the reaction cycle. Each reaction is also self-limiting so that the gas-surface reaction stops when all surface sites are converted. Each reaction cycle that proceeds to completion produces a monolayer of coating that covers all topographical contours of the surface that are reactive to the gaseous precursors—ALD is not line-of-sight limited. The reaction sequence is repeated until the desired thickness of coating is reached. The self-limiting and cyclic nature of the ALD process makes it superior in its thickness and chemical precision compared to other thin film fabrication techniques. This technology can be applied to nearly any material and particularly excels when used on/in high surface area and porous materials, including powders and porous membranes like separators.

However, due to the homogeneous and uniform coatings that are anticipated by deploying ALD coatings on high surface area, porous substrates such as battery separators, excess materials are oftentimes deposited beyond what is useful or necessary to achieve a particular functional benefit. Battery separators are multifunctional and attributes such as flexibility, wettability, permeability, robustness at higher voltage conditions, temperature stability, shut-down properties, and so on, are individually and cumulatively important for the proper longevity of a battery. Additionally, substrates are ideally fully dried prior to receiving an ALD treatment and processes typically operate under vacuum conditions that are difficult to integrate into an in-line battery manufacturing unit operation. Uniform, nanoscale ALD coatings are useful when applied to anode and cathode material particles prior to being mixed into a slurry and cast on an electrode as the entirety of exposed particle surfaces can be protected from deleterious effects during battery operation. The hallmark of an ALD coating as applied to separators is the deposition uniformity between the initially impinged surface (here an upper surface), the internal surfaces of the separator, and the opposing side of the porous separator. ALD can produce a ceramic ‘exoskeleton’ on external surfaces and within the internal surfaces of the separator itself that can allow it to become impervious to shrinkage up to the sintering temperature of the ceramic material. However, this adversely affects the so-called ‘shut-down properties’ of a separator, which is a safety feature known to inhibit thermal runaway based on the intentional collapsing of pores to prevent electrical conduction pathways from forming. In many cases, a superior coated separator may have an upper region having a first coating thickness, an internal region having a lower coating thickness than the upper region, and a bottom region that has a lower coating thickness than the internal region or no coating at all. Oftentimes the coating in the internal region or the bottom region comprises nodules, discrete deposits, semi-continuous or discontinuous coated regions, or similar, and can be quantified using weight loading percentages present within a certain slice or region along the cross-section of the separator.

It has been discovered that the Reactive Drying (RD) process of the present disclosure can improve key attributes of separators, while producing a multifunctional second phase that can be tailored by application to produce a separator that is ideal for batteries that operate under different conditions for different applications. The in-line RD process developed in the present disclosure can also leverage precursors that are commonly used in ALD processes, and can even be carried out using ALD equipment that is modified to accommodate the differing process steps of the two techniques.

Standard drying procedures for Electrodes (NMP based): After the electrode slurry is cast, electrodes are dried in a 120 C oven at atmosphere for 10 min. At this time the electrode loadings are determined and calendering occurs. Prior to cell builds, electrodes are dried under vacuum at 120 C overnight.

Standard drying procedures for Electrodes (water-based): After the electrode slurry is cast, electrodes are dried at 120 C for 30 minutes. At this time the electrode loadings are determined and calendering occurs. Water-based electrodes are then dried overnight at 150 C before storage in a dry box. Prior to cell builds, electrodes are dried under vacuum overnight at 120 C as is the case with all electrodes prior to build.

Standard drying procedures for Separators: Dried under vacuum at 60 C for 1 hour before being stored in the glovebox.

Moisture Measurement Technique: Moisture is measured using an Arizona Instruments Computrac Vapor Pro Moisture Analyzer (model number CT-3100-L)

### Sample Preparation

1. Tare a clean, empty sample bottle, include the septum and cap.
2. Weigh out the appropriate sample using an analytical balance (See Table A for recommended sample amount or use the equation below.) Minimum Sample (grams)=0.02/Expected Moisture (%)
3. Record weight of loaded sample bottle and the sample within.
4. Ensure that the PTFE/hydrophobic side of the septum is to the inside of the bottle.

TABLE A
Sample Size (Note: These are only guidelines and actual
experimentation should be used to determine appropriate
sample size for desirable speed and accuracy.

| Expected | |
|---|---|
| Moisture (% or ppm) | Use (grams) |
| 0.001-0.015% or | 1.5-2 |
| 50-150 ppm | |
| 0.015%-0.035% or | 0.5-1.5 |
| 150-350 ppm | |
| 0.035%-0.075% or | 1-2 |
| 350-750 ppm | |
| 0.075%-0.15% | 0.5-1 |
| 0.150-0.350% | 0.2-0.5 |
| 0.350-0.750% | 0.1-0.2 |
| 0.750%1.50% | 0.05-0.1 |

Electrode powders, finished electrodes and separators are typically dried to below 500 ppm of moisture, oftentimes below 250 ppm of moisture, and sometimes below 50-100 ppm of moisture. Electrode powders receive a second drying treatment as a byproduct of the electrode drying process described above.

The moisture content of electrode powders, finished electrodes and separators were measured prior to and after storage in different relative humidity environments. Samples were stored/handled in their respective environment for a time duration commensurate with the total amount of time each material is stored and/or handled during a standard cell build process in a dry room environment.

Storage/handling in a 1% relative humidity glove box (drybox conditions): For an electrode powder devoid of a ceramic coating, the amount of moisture uptake may be 20-30 ppm. For an electrode powder with a ceramic coating, the amount of moisture uptake may be 40-60 ppm, due to the hygroscopic nature of the coating. For a finished electrode or separator devoid of a ceramic coating, the amount of moisture uptake may be 100-150 ppm. For a finished electrode or separator with a ceramic coating, the amount of moisture uptake may be 200-250 ppm, due to the hygroscopic nature of the coating.

Storage/handling in a ˜10-20% relative humidity (conventional laboratory environment): For an electrode powder devoid of a ceramic coating, the amount of moisture uptake may be 130-210 ppm. For an electrode powder with a ceramic coating, the amount of moisture uptake may be 250-350 ppm due to the hygroscopic nature of the coating. For a finished electrode or separator with a ceramic coating, the amount of moisture uptake may be 400-500 ppm. For a finished electrode or separator with a ceramic coating, the amount of moisture uptake may be 500-800 ppm, due to the hygroscopic nature of the coating.

Storage/handling in an ˜80-100% relative humidity environment: For all aforementioned substrates, the amount of moisture uptake may be similar at 2000-3000 ppm. The hygroscopic nature of the ceramic coating does not appear to further increase the amount of moisture uptake relative to any uncoated counterparts as the moisture uptake of each is substantial. As expected, all electrode powders, finished electrodes and separators formulated into batteries yielded poor electrochemical performance.

In one embodiment, a Reactive Drying (RD) process is used to expose a moisture-reactive precursor to a moving web comprising moisture. The first objective in establishing an in-line RD process is to determine the required speed of the moving web or sheet, which is linked to the cell manufacturing line speed. Typical industrial ranges may be 0.1 to 1 m/min, 1 to 10 m/min, 10 to 50 m/min, 50 to 100 m/min, etc.

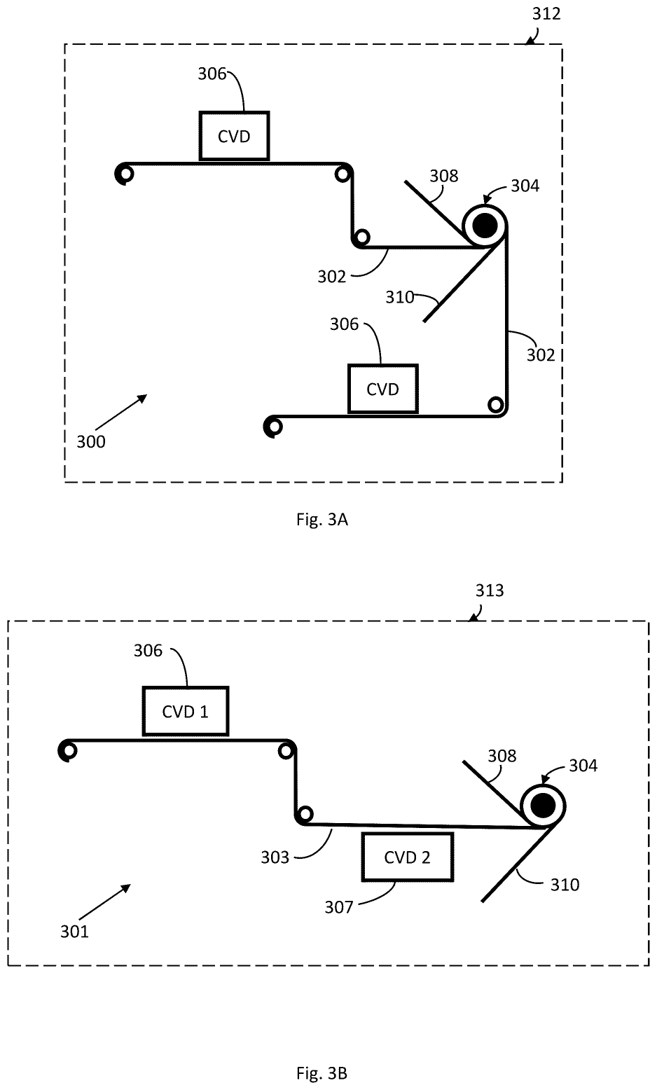

An example of the RD process that can be carried out in a modified ALD system is shown in FIG. 2. RD system 200 provides an idealized depiction of a continuous, spatial ALD process that conveys a moving web 202 having surface functional groups through or past repeating regions 204, 206 of isolated, locally concentrated but spatially alternating precursors. In the ALD process, any point on web 202 experiences the A-B-A-B-A-B sequence of precursor exposure with greatly enhanced speed: 0.01-0.05 Å/sec temporally, and up to 2-10 Å/sec spatially. The width of the region of precursor concentration (mm) in the direction of web movement multiplied by the speed of the web 202 (m/s) relative to the regions 204, 206 determines the residence time(s) of the precursor(s) while the space between the regions 204, 206 of precursor concentration (mm) and web speed (m/s) relative to that space determines the purge time(s). In an actual RD system, the total precursor A flux administered to a moving web 202 from region 204 would be substantially larger, sometimes at least 50-100 times larger, than what would be administered using a vacuum-based ALD system, since the objective of the inventive process is both the rapid reduction of total moisture, and inclusion of a non-linear weight loading profile with respect to penetration depth rather than uniform, conformal coating in a step-wise growth mechanism.

A further contrast between RD and ALD is that since the in-line RD process leverages total moisture (e.g., latent moisture and uptaken moisture) in the separator substrate, which obviates the need for the substrate to have a sufficiently high density of surface functional groups such as is the case for ALD. Moisture may be present at the surfaces (upper, lower or internal), or it may be embedded within the materials, such as structural water or moisture trapped within a polymeric material. The resulting growth structure of an in-line RD process on a polymeric substrate having trapped moisture, would be in the form of an inclusion within the substrate, which would inherently create a localized expansion adjacent to the inclusion site. This elucidates the value in quantifying the amount of ceramic material present from the in-line CVD process using weight percent of the ceramic relative to the substrate and void space within a particular region or zone.

Web 202 of FIG. 2 is a separator that can be made of a polyolefin (ex. polypropylene). RD precursor A can be trimethylaluminium (TMA), or any moisture-scavenging precursor that can carry out the RD process at temperatures that will not melt, soften or deform the substrate. The reaction between this RD precursor A and moisture in web 202 result in aluminum oxide (Al₂O₃) coating 208 or deposits on web 202 from the following chemical reaction:

Al(CH3)3+3/2H2O→½Al2O3+3CH4 (2)

Any unreacted RD precursor A from chemical reaction 2 is removed by the inert gas (ex. N2) curtain 210 of FIG. 2 and exhausted away from web 202 by system 200. In this in-line RD process, unreacted precursor A could be present if, for example, the flux of precursor A was greater than the web speed and density of moisture accessible to precursor A at a steady state penetration depth in view of pressures, temperature, flow rates and web permeability. Similarly, an in-line RD process designed to fully react precursor A with moisture would necessitate the flux of precursor A to be less than the web speed and density of latent moisture accessible to precursor A at a steady state penetration depth in view of pressures, temperature, flow rates and web permeability.

As described above, an ALD process carried out in ALD system 200 requires that both precursor A and precursor B are sequentially injected into a moving substrate having reactive surface functional groups that can nucleate an ALD coating that grows outward from these surface sites. In this in-line RD process as applied to a battery separator, moisture may be present on the surfaces of the substrate that are contained within the interior of the torturous polymer network; however, this source of moisture would be easier to remove during conventional thermal drying steps used in current cell manufacturing operations. For battery separators, moisture is also present within the polymeric material itself, which is more difficult to remove without undesirably long times or elevated drying temperatures that are inherently limited by material properties. Also as described above, when RD precursor A reacts with latent moisture present within the polymeric material itself, the solid reaction product may form or nucleate as a ceramic inclusion. It has been discovered that the latent moisture within the polymeric material that is accessible to RD precursors is beneficial, as is surface moisture. Thus, another object of this invention is the pre-treating of the normally dry separator with humidity (to apply moisture in the same non-linear fashion as described above) to intentionally increase the total moisture content prior to carrying out the in-line RD process, to tailor the loading of the ceramic material along the penetration depth of the separator itself. In this case, RD precursor A of position 204 of modified ALD system 200 could be H2O, O3, N2O, CO2, NH3 or another pretreatment vapor, and precursor B at position 206 could represent trimethylaluminum or other metal-containing precursor that can react with moisture, or another pretreatment vapor that can adsorb to internal surfaces and diffuse into the polymeric material itself (and an RD chemical could be located at a precursor C position, which is not shown). Additional precursor and purging slots can be incorporated to further produce ALD-like layers or molecularly grafted materials onto the surfaces of the RD formed materials, provided that the moisture level is not increased and the profiles remain intentionally non-linear.

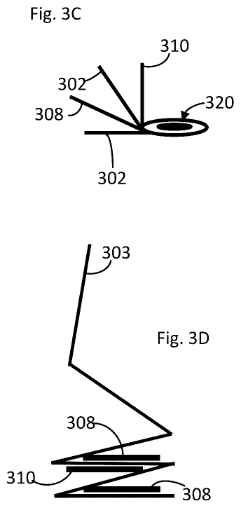

FIG. 3A shows a system 300 that forms battery cells. Separators 302 are provided to cylindrical winding 304 after being formed from RD systems 306. Anode 308 and cathode 310 are provided from any potential source, such as a spool. System 300 can be used in a dry or humidity-controlled environment, or can be contained in a system housing 312 that itself is dry or humidity-controlled. FIG. 3B shows another system that uses a prismatic winding 320. Separators 302 can be formed as described in FIG. 2 and provided to prismatic winding 320 as shown in FIG. 3A. System 301 shows an embodiment of the present invention where a first RD system 306 carries out a first chemical drying process that penetrates the separator from a first surface, and a second RD system 307 (that may utilize the same reactive precursor or a different reactive precursor as is used in RD system 306) carries out a second chemical drying process that penetrates the separator from a second surface. RD system 306 and 307 may be positioned sequentially to one another such as is depicted in system 301, or can be positioned to occur simultaneously to one another to control the internal pressure and permeability of reactive precursors within and through the separator, respectively. Anode 308 and cathode are wound so that they are separated by separators 302. FIG. 3C shows a further system that uses z-folding to make a battery cell. Separator 302 can be formed as described in FIG. 2 and provided to prismatic winding 320 as shown in FIG. 3A. Anode 308 and cathode 310 are alternately disposed between the folds of separator 302. For the systems shown in FIGS. 3A-B, the maximal benefit of the RD process for chemical drying is preferably integrated in the battery manufacturing process directly prior to the cell stacking (or winding, folding) system and operates at the speed of the existing subsequent unit operation in the battery manufacturing process. Eventually it is envisaged that this chemical drying system may reduce the footprint of existing battery unit operations, or eliminate one or more steps entirely.

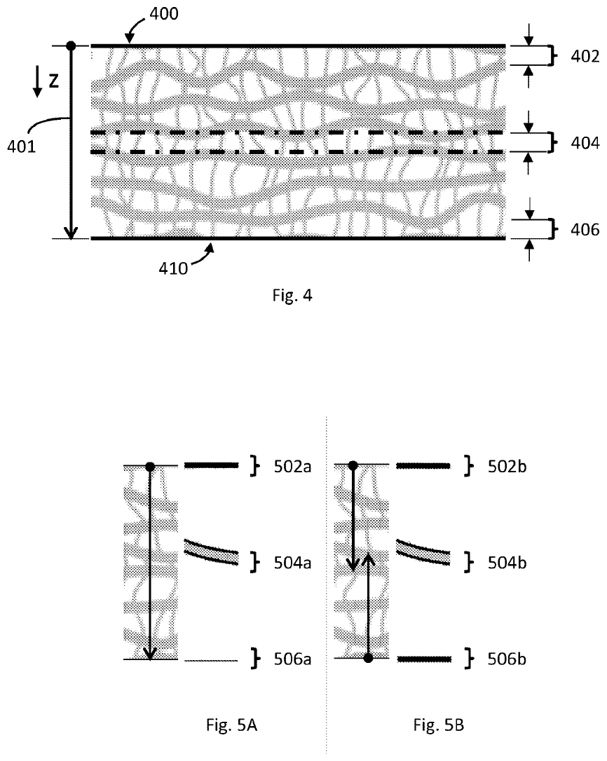

A feature of the invention is the resulting ceramic materials that can be formed on and within the battery separator as a secondary byproduct of this Reactive Drying process. FIG. 4 depicts a drawing of a separator used in battery manufacturing, which has a first (or upper) surface 400, a definable thickness 401 in the z-direction, an opposing second (or lower) surface 410, and regions 402 (upper), 404 (middle) and 406 (lower) associated with the penetration depth from surface 400. Upper region 402 represents the top-most 10% of the separator (0-10% times thickness 401); middle region 404 represents the middle 10% of the separator (45-55% times thickness 401); lower region 406 represents the bottom-most 10% of the separator (90-100% times thickness 401). An exemplary RD process shown in FIG. 3B may form ceramic material using RD system 306 via upper surface 400, within upper region 402, then middle region 404, and (depending on operating parameters) then lower region 406 and potentially out lower surface 410. An optionally-deployed second RD system 307, would be positioned on the bottom side of the separator, and would form ceramic material via surface 410, first within lower region 406, then middle region 404, and (depending on operating parameters) then upper region 402 and potentially out surface 400.

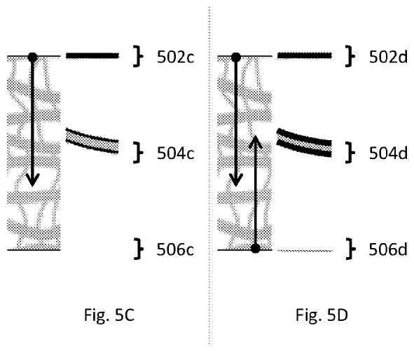

FIG. 5 depicts four different achievable profiles that result from four different Embodiments A-D described in more detail below. The profiles can be identified by the relative amount of ceramic material that can be formed in the three regions 502, 504 and 506, which generally correspond to upper region 402, middle region 404 and lower region 406 above.

FIG. 5A shows the profile of Embodiment A, wherein the amount of material formed (measured by estimated weight loading) decreases relatively linearly with penetration depth. Alternatively, or in addition to, the amount of material formed in middle region 504a is half (+/−10%) of the sum of the material formed in upper region 502a and lower region 506a, and wherein the amount of material formed in lower region 506a is non-zero. Embodiment A requires a sufficiently high Reactive Drying precursor flow relative to the lateral speed of the moving web to form a non-zero amount of material in the slice that is positioned furthest from the RD system. By way of example, if the total moisture of a separator is 400 ppm and the moisture is distributed evenly (i.e., each 10% region comprises on average 40 ppm of the 400 ppm total moisture), the amount of RD precursor that reaches upper region 502a must be sufficient to form 40 ppm of the ceramic material selected without providing additional moisture to the system. If the desirable amount of ceramic material in lower region 506a is 10 ppm to achieve a particular functional benefit, then the target amount of ceramic material in middle region 504a in this exemplary Embodiment A profile would be approximately 23-27 ppm. In total, if the amount of material decreased linearly with penetration depth, the final moisture content would be 150 ppm, and a total of 250 ppm of ceramic material would be present throughout the entirety of the separator

FIG. 5B shows the profile of Embodiment B, wherein a first RD system (e.g. RD system 306 of FIG. 3B) and a second RD system (e.g. RD system 307 of FIG. 3B) are deployed on opposing surfaces of the separator. The profile of Embodiment B, wherein the amount of material formed (measured by estimated weight loading) in middle region 504b is less than what a first RD system 306 applies to upper region 502b, and less than what a second RD system 307 applies to lower region 506b, with the provisio that the middle region 504b comprises material formed from both first RD system 306 and second RD system 307. Alternatively, or in addition to, the amount of material formed in middle region 504b is between approximately 25% and 75% of the material formed in either upper region 502b, lower region 506b or both, and wherein the amount of material formed in middle region 504b is non-zero. By way of example, if again the total moisture of a separator is 400 ppm and the moisture is distributed evenly, the amount of RD precursor that reaches middle region 504b must be sufficient to form approximately 10-30 ppm of the ceramic material selected without providing additional moisture to the system, provided the ceramic material formed in one or more of upper region 502b and lower region 506b reaches 40 ppm. In an idealized example, if the amount of ceramic material in upper region 502b, middle region 504b and lower region 506b was 40 ppm, 25 ppm and 40 ppm and the profiles were linear, the amount of total ceramic material would be approximately 333 ppm, and about 5/6 of the total moisture would be chemically dried or titrated in this system.

FIG. 5C shows the profile of Embodiment C, wherein the amount of material formed (measured by estimated weight loading) decreases parabolically with penetration depth, such that the precursor is fully consumed prior to reaching any moisture in lower region 506c (i.e., the amount of material formed in lower region 506c is zero). Alternatively, or in addition to, the amount of material formed in middle region 504c may be approximately 25-75%, 25-35%, 50%+/−10%, or 65-75% of the of the material formed in upper region 502c and again wherein the amount of material formed in lower region 506c remains 0 ppm. Embodiment C requires a sufficiently high lateral speed of the moving web relative to the Reactive Drying precursor flow to form an appreciable amount of material in the middle region 504c, without reaching lower region 506c that is positioned furthest from the RD system. Embodiment C may be produced using the aforementioned relative precursor to substrate flux ratios when using a separator having uniformly distributed total moisture, or can be produced using a first humidification step prior to or within RD system 306 (e.g. using ‘Precursor A’ zone 204 of FIG. 2, for example) followed by the administration of an appropriate amount of metalorganic or other moisture-reactive precursor (e.g. the Reactive Drying precursor is administered in ‘Precursor B’ zone 206 of FIG. 2) while the separator is moving through the drying system at sufficiently high speed.

FIG. 5D shows the profile of Embodiment D, wherein the amount of material formed (measured by estimated weight loading) in middle region 504d is the same or only slightly lower than the weight loading in upper region 502d. The profile may exhibit a slightly decreasing weight loading between upper region 502d to middle region 504d with respect to penetration depth from the upper surface; or the profile may exhibit up to a uniform weight loading between upper region 502d to middle region 504d with respect to penetration depth from the upper surface. Independent of the profile exhibited between upper region 502d and middle region 504d, Embodiment D provides a substantially lower, but non-zero, weight loading produced in lower region 506d (i.e., the amount of material formed in lower region 506d is non-zero) relative to the weight loading in middle region 504d. Alternatively, or in addition to, the amount of material formed in middle region 504d may be approximately 75% to 100% of the of the loading of material formed in upper region 502d and the amount of material formed in lower region 506d may be approximately 1-25% of the amount of material formed in upper region 502d. Embodiment D is similar to Embodiment B in that an exemplary RD process shown in FIG. 5D may form ceramic material using RD precursor A using a first RD system 306 via upper surface 400, within upper region 502d, then middle region 504d, and require that the RD precursor A be fully exhausted prior to reaching lower region 506d. Thus, a second RD system 307 that is positioned on the bottom side of the separator would form ceramic material within lower region 506d, then middle region 504d, and (depending on operating parameters) then upper region 502d and potentially out surface 400. The flow rate from first RD system 306 is inherently larger than that of second RD system 307 to produce the desired profile of Embodiment D.

One particular feature of Embodiment D is that the precursor used in upper RD system 306 may be different from the precursor used in lower RD system 307, such that the ceramic material formed in upper region 502d would be different from the ceramic material formed in lower region 506d. Thus, by design, middle region 504d would comprise a mixture of both ceramic materials, either in the form of a mixed-metal ceramic, discrete regions of distinct ceramic materials or combinations thereof. One benefit of Embodiment D is that a cathode-stable surface material can be produced on the cathode-facing surface of the separator, while an anode-stable surface material can be produced on the anode-facing surface of the separator.

The formed materials of choice for the RD processes described in any of the embodiments above may comprise at least one oxide (i.e., the byproduct of a reaction that reduces or titrates the amount of total moisture in the system), of a non-metal, semi-metal, metalloid or metal. The formed material may comprise a hydroxide, oxyhydroxide, nitride, oxynitride, phosphate, oxyphosphate, sulfide, oxysulfide, sulfate or oxysulfate. The design criteria is intended to satisfy the following constraints: i) at least one RD precursor must be moisture reactive; ii) the minimum flux of RD precursor must be sufficient to be able to reduce the total moisture of the target substrate by at least 25%; iii) the formed materials should be stable at an operating voltage range of 0.01 to 5.0 Volts; iv) optionally, the formed materials are able to incorporate Li+, Na+ and/or K+ to produce a structure that exhibits a higher ionic conductivity than the formed materials devoid of these elements. In a lithium-ion battery, the Li+ incorporated into the structure may be derived from a lithium-containing RD precursor and applied during the in-line RD process, or it may be derived from another component of the cell such as from a Li+ containing cathode, anode or electrolyte. Compounds having a bandgap of 2.0 eV or greater are of particular interest for materials applied to separators and certain electrodes during the battery fabrication process, which are conventionally referred to as wide-bandgap semiconductors. II—IV and III-V semiconductor families are of interest as they have been shown to accommodate Group I ions Li+, Na+ and/or K+, and form complexes with oxides that would be inherent to a chemical drying process. Examples of complexes comprising III-V semiconductor materials include nitrides of boron, aluminum or gallium, the cations of which can be incorporated using precursors that are sensitive to moisture, provided the formed materials applied to a porous separator are not electrically conductive; and the complexes of which can incorporate Li+, Na+ and/or K+. Lithium boron oxynitride, Lithium aluminum oxynitride and Lithium gallium oxynitride are three representative compounds that can be applied to various substrates described herein. Lithium zinc oxide is another complex that can be beneficial to RD process for separators. Of further interest are compounds that can scavenge HF and create fluorinated complexes upon cycling of a battery material. Al₂O₃ is useful to reduce moisture during the fabrication of a battery, and incorporate lithium and fluorine upon cycling the battery. After cycling a battery at least 25 times, an aluminum cation applied to an electrode or a separator as part of an RD process of any Embodiment A-D above may convert into a lithium aluminum oxyfluoride type compound (or lithium aluminate, lithium aluminum fluoride or aluminum fluoride or combinations thereof), while reducing the amount of total moisture present on the electrode or separator during fabrication of the battery. Cations on the periodic table having an atomic number of 40 and lower are of interest as RD materials as heavier elements increase weight loadings of cell components unnecessarily. Transition metal cations V, Cr, Mn, Fe, Co, Ni and Cu are not of interest because these may undergo redox reactions with the electrolyte within the battery cell and create degradation pathways that adversely affect electrode material stability. Preferred RD processes are based upon precursors that can deliver a vapor of a compound comprising Li, B, C, Na, Mg, Al, Si, K, Ca, Sc, Ti, Zn, Ga, Ge, Sr, Y or Zr, wherein the compound is moisture-reactive at a temperature that is below the softening or degradation temperature of the substrate to be chemically dried.

In some embodiments comprising separator substrates, longer-chained molecules that can be delivered to and through surface 400 (or 410) in the vapor phase that comprise silicon and at least one hydroxyl group are beneficial in drying processes. Silanol and siloxane type materials may further comprise an additional non-silicon metal, metalloid or non-metal that further enhances the functionality of the deposited material. Specific elements include silicon and one or more of boron, aluminum, lithium, titanium, zirconium, fluorine, nitrogen, sulfur or phosphorous. Precursors containing a silyl-amide functionality are also preferred in some embodiments, particularly embodiments where the chemical drying process is being applied to a ceramic-coated separator. A feature of this type of Reactive Drying process is the ability to reduce total moisture of a substrate by at least 25%, while increasing the hydrophobicity of the substrate as measured by increasing the contact angle of a droplet of water by at least 5° relative to the substrate devoid of the hydrophobic coating. Alternatively, or in addition to, the surface tension of the substrate as measured in common units such as dynes/cm2, is increased by at least 10% due to the Drying process using any coating described throughout this specification.

Suitable precursors may include one or any combination of lithium t-butoxide, lithium trimethylsilylamide, lithium (2,2,6,6-tetramethyl-3,5-heptanedionate), diborane, trimethylboron, triethylboron, triisopropylboroate, triphenylborane, tris(pentafluorophenyl) borane, carbon tetrabromide, carbon tetrachloride, ethanediol, ethanolamine, diethylamine, ethylene diamine, maleic anhydride, sodium t-butoxide, sodium trimethylsilylamide, sodium (2,2,6,6-tetramethyl-3,5-heptanedionate), bis(cyclopentadienyl) magnesium (II), bis(pentamethylcyclopentadienyl) magnesium (II), bis(pentaethylcyclopentadienyl) magnesium (II), aluminum sec-butoxide, aluminum tribromide, aluminum trichloride, diethylaluminum ethoxide, dimethylaluminum isopropoxide, tris(ethylmethylamido)aluminum, tris(dimethylamido)aluminum, triethylaluminum, triisobutylaluminum, trimethylaluminum, tris(diethylamido)aluminum, tris(ethylmethylamido)aluminum, 2,4,6,8-tetramethylcyclotetrasiloxane, dimethoxydimethylsilane, disilane, methylsilane, octamethylcyclotetrasiloxane, silane, tris(isopropoxy) silanol, tris(tert-butoxy) silanol, tris(tert pentoxy) silanol, (3-aminopropyl)triethoxy silane, N-sec-butyl(trimethylsilyl)amine, chloropentamethyldisilane, hexamethyldisilazane, silicon (IV) chloride, silicon (IV) bromide, pentamethyldisilane, tetraethylsilane, N,N′,N″-tri-tert-butylsilanetriamine, potassium t-butoxide, potassium trimethylsilylamide, potassium (2,2,6,6-tetramethyl-3,5-heptanedionate), calcium bis(2,2,6,6-tetramethyl-3,5-heptanedionate), tris(2,2,6,6-tetramethyl-3,5-heptanedionato) scandium (III), bis(diethylamido)bis(dimethylamido) titanium (IV), tetrakis(diethylamido) titanium (IV), tetrakis(dimethylamido) titanium (IV), tetrakis(ethylmethylamido) titanium (IV), titanium (IV) bromide, titanium (IV) chloride, titanium (IV) fluoride, titanium (IV) tert-butoxide, titanium (IV) isopropoxide, titanium (IV) ethoxide, titanium (IV) methoxide, titanium (IV) isopropoxidebis(2,2,6,6-tetramethyl-3,5-heptanedionate), dichlorotitanium (IV) oxide, diethylzinc, dimethylzinc, diphenylzinc, bis(2,2,6,6-tetramethyl-3,5-heptanedionate) zinc (II), bis(pentafluorophenyl) zinc, gallium tribromide, gallium trichloride, triethylgallium, triisopropylgallium, trimethylgallium, tris(dimethylamido) gallium, tri-tert-butylgallium, digermane, germane, tetramethylgermanium, germanium (IV) fluoride, germanium (IV) chloride, hexaethyldigermanium (IV), hexaphenyldigermanium (IV), tributylgermanium hydride, triphenylgermanium hydride, strontium tetramethylheptanedionate, tris(N,N-bis(trimethylsilyl)amide) yttrium (III), yttrium (III) tris(tert-butoxide), yttrium (III) triisopropoxide, yttrium (III) tris(2,2,6,6-tetramethyl-3,5-heptanedionate), tris(butylcyclopentadienyl) yttrium (III), tris(cyclopentadienyl) yttrium (III), yttrium 2-methoxyethoxide, zirconium (IV) dibutoxide (bis-2,4-pentanedionate), zirconium (IV) 2-ethylhexanoate, zirconium tetrakis(2,2,6,6-tetramethyl-3,5-heptanedionate), bis(cyclopentadienyl) zirconium (IV) dihydride, bis(methyl-n-cyclopentadienyl) methoxymethylzirconium, tetrakis(diethylamido) zirconium (IV), dimethylbis(pentamethylcyclopentadienyl) zirconium (IV), tetrakis(dimethylamido) zirconium (IV), tetrakis(ethylmethylamido) zirconium (IV), zirconium (IV) bromide, zirconium (IV) chloride, zirconium (IV) tert-butoxide, ZyALD, phosphine, tert-butylphosphine, tris(trimethylsilyl) phosphine, phosphorous oxychloride, triethylphosphate, trimethylphosphate, or other vaporous or vaporizable precursors. Additionally, moisture reactive metal salts or hydroxides that are dissolved in a suitable solvent, can be used as a Reactive Drying precursor administered via an injection device, nozzle, spray device, vaporizer, or sonicator.

Any deposition process that provides a precursor that reacts with a surface and further scavenges water can be used. Furthermore, other precursors can be used that react with water, such as metals from various organometallic and metal organic precursors using H2O2 (in H2O) or O3 as the other precursor. Plasma-based processes are also preferred in instances where the direct reaction between a precursor and total moisture is challenging due to accessibility, steric hindrance or similar. Any element or molecule that oxidizes and can create a vapor-phase leaving group is considered within the possible variations of the present disclosure.

The RD system disclosed can be adapted from a roll-to-roll system that uses spatial ALD principles. The precursors can be exposed to any moving web or substrate utilized in a battery manufacturing process, including the separator, fabricated electrodes and/or current collectors linearly as shown in the figures, or can be provided using a drum-style system where substrates maintain a fixed radius of curvature during the drying process.

### EXAMPLES

### Example 1—Reactive Drying (RD) of a Pre-Dried Moving Separator

A continuous web of a pre-dried commercial polyethylene (PE) separator was inserted into a custom built RD reactor, which was based upon a vapor deposition reactor designed to accommodate a moving web. The PE separator had a thickness of 20 microns and was uncoated. Prior to insertion into the RD reactor, the moisture of the separator was measured in accordance with ASTM D7191-10: Standard Test Method for Determination of Moisture in Plastics by Relative Humidity Sensor. The moisture content of the separator was measured to be 255±34 ppm based upon measurements from three discrete samples.

Trimethylaluminum (TMA) was used as the chemical drying agent in the RD reactor. The web speed was set to 10 meters per minute (m/min) and a TMA flow rate impinging the upper side of the porous separator was set to 50 standard cubic centimeters per minute (sccm) to minimize excess TMA from exiting through the lower side of the porous separator. The CVD reactor was operated at an ambient pressure of approximately 670 Torr, and the reactor temperature was set to 70 C. Approximately ten meters of porous separator were produced in the experiment, and the first and last four meters were trimmed off to minimize any start-up and shut-down effects of the drying process.

Three samples were taken from the steady-state portion of the chemically-dried separator such that the moisture content of the finished product could be measured. The moisture content of the dried separator was 114±16 ppm. Additional samples from nearby locations were cross-sectioned and analyzed using an SEM with EDS capabilities to determine the weight loading of aluminum produced (due to the conversion of moisture to aluminum oxide) within the upper region, middle region and lower region. The measured weight loadings of aluminum were 0.03%, 0.02% and 0.00% in the upper region, middle region and lower region, respectively.

### Example 2—RD of a Non Pre-Dried Moving Separator

The same PE separator having a thickness of 20 microns was prepared for loading into the same Reactive Drying system as Example 1, again using TMA as the drying agent. Prior to insertion into the RD reactor, the moisture of the separator was measured to be 631±45 ppm based upon measurements from three discrete samples. The same target web speed, flow rate, operating pressure and temperature and sampling procedure as described in Example 1 were used. The moisture content of the chemically dried separator was 132±19 ppm. The measured weight loadings of aluminum were 0.06%, 0.03% and 0.00% in the upper region, middle region and lower region, respectively.

### Example 3—RD of a Non Pre-Dried Moving Separator

The same PE separator having a thickness of 20 microns was prepared for loading into the same Drying system as Example 1. Prior to insertion into the RD reactor, the moisture of the separator was measured to be 344±40 ppm based upon measurements from three discrete samples. Diethylzinc (DEZ) was used as the chemical drying agent in the RD reactor. The same target web speed, flow rate, operating pressure and temperature and sampling procedure as described in Example 1 were used. The moisture content of the chemically dried separator was 102±22 ppm. The measured weight loadings of zinc were 0.08%, 0.06% and 0.02% in the upper region, middle region and lower region, respectively.

### Example 4—RD of a Non Pre-Dried Moving Separator

The same PE separator having a thickness of 20 microns was prepared for loading into the same Reactive Drying system as Example 1. Prior to insertion into the RD reactor, the moisture of the separator was measured to be 605±51 ppm based upon measurements from three discrete samples. Triethylboron (TEB) was used as the chemical drying agent in the RD reactor. The same target web speed, flow rate, operating pressure and temperature and sampling procedure as described in Example 1 were used. The moisture content of the chemically dried separator was 201±27 ppm. The measured weight loadings of boron were 0.03%, 0.02% and 0.00% in the upper region, middle region and lower region, respectively.

### Example 5—RD of a Non Pre-Dried Moving Separator

The same PE separator having a thickness of 20 microns was prepared for loading into the same Reactive Drying system as Example 1. Prior to insertion into the RD reactor, the moisture of the separator was measured to be 510±65 ppm based upon measurements from three discrete samples. Titanium isopropoxide (TTIP) was used as the chemical drying agent in the RD reactor. The same target web speed, flow rate, operating pressure and temperature and sampling procedure as described in Example 1 were used. The moisture content of the chemically dried separator was 218±29 ppm. The measured weight loadings of titanium were 0.06%, 0.05% and 0.00% in the upper region, middle region and lower region, respectively.

### Example 6—RD of a Non Pre-Dried Moving Separator

The same PE separator having a thickness of 20 microns was prepared for loading into the same Drying system as Example 1, again using TMA as the drying agent. Prior to insertion into the RD reactor, the moisture of the separator was measured to be 608±59 ppm based upon measurements from three discrete samples. The same target web speed, operating pressure and temperature and sampling procedure as described in Example 1 were used, however a TMA flow rate of 100 sccm was used. The moisture content of the chemically dried separator was 108±39 ppm. The measured weight loadings of aluminum were 0.07%, 0.07% and 0.02% in the upper region, middle region and lower region, respectively.

### Example 7—RD of a Non Pre-Dried Moving Separator

The same PE separator having a thickness of 20 microns was prepared for loading into the same Reactive Drying system as Example 1, again using TMA as the drying agent. Prior to insertion into the RD reactor, the moisture of the separator was measured to be 498±39 ppm based upon measurements from three discrete samples. The same target operating pressure and temperature and sampling procedure as described in Example 1 were used, however the TMA flow rate was returned to 50 sccm, while the web speed was reduced to 5 m/min. The moisture content of the chemically dried separator was 98±9 ppm. The measured weight loadings of aluminum were 0.06%, 0.05% and 0.04% in the upper region, middle region and lower region, respectively.

Comparative Example 1-ALD on a pre-dried separator in a vacuum system A 2 meter web of the commercial PE separator used in Example 1 was placed into a viscous flow ALD reactor and pumped down to rough vacuum (<1 Torr) and brought to an operating temperature of 70 C. Trimethylaluminum (TMA) and water were used as the ALD precursors to grow aluminum oxide layers. Sequential exposures of TMA and water were applied to the static separator for 30 seconds each, separated by two minute purge times. A total of 10 ALD cycles were applied.

The moisture content of the separator prior to coating was measured to be 248±31 ppm; three samples were taken from the center of the ALD-coated separator such that the moisture content of the finished product could be measured. The moisture content of the ALD coated separator was 261±16 ppm. Additional samples from nearby locations were cross-sectioned and analyzed using an SEM with EDS capabilities to determine the weight loading of aluminum produced (from the aluminum oxide ALD layers) within the upper region, middle region and lower region. The measured weight loadings of aluminum were 0.24%, 0.23% and 0.23% in the upper region, middle region and lower region, respectively. It is hypothesized that since water vapor is included in the ALD process, there is no chemical drying mechanism that would serve to reduce the moisture content further than what pre-drying provides.

1. A method of drying a porous sheet, comprising:
providing a porous sheet comprising a material; the porous sheet having two major surfaces and being defined by three mutually-perpendicular directions of thickness, height and width, wherein thickness is the smallest dimension; wherein the material comprises a moisture content of at least 200 ppm (or at least 250 ppm, or at least 300 ppm, or in the range of 200 to 1000 ppm) as measurable by ASTM D7191-10;
the porous sheet comprising:
an upper region defined as the cross-sectional area extending from the upper surface to 10% of the thickness of the porous sheet, and along the width of the porous sheet;
a middle region defined as the cross-sectional area beginning at a point that is 45% of the thickness of the porous sheet from the upper surface, extending to a distance that is 45% of the thickness of the porous sheet from the lower surface, and along the width of the porous sheet;
a lower region defined as the cross-sectional area extending from the lower surface to 10% of the thickness of the porous sheet, and along the width of the porous sheet;
exposing the upper region of the porous sheet to a gaseous precursor, wherein the gaseous precursor comprises one or more elements selected from the group consisting of Li, B, C, Na, Mg, Al, Si, K, Ca, Sc, Ti, Zn, Ga, Ge, Sr, Y and Zr, and is reactive with water;
wherein the step of exposing is conducted for a limited time and/or with a limited precursor such that the concentration by mass of said one or more elements in the upper region is at least 10% (or at least 20% or in the range of 10 to 70% or 10 to 50%) higher than the concentration of said one or more elements in the middle region and is in the range of 0.01% to 1%, or 0.01 to 0.5%, or 0.01 to 0.1%, or 0.01 to 0.05%.

2. The method of 1 wherein, following said step of exposing, the moisture content of the porous sheet is 190 ppm or less, or 170 ppm or less, or in the range of 50 to 190 ppm.

3. The method of claim 1 wherein the material is a carbon-based polymer, preferably polyethylene or polypropylene, or PVDF, PTFE, PLA, or polystyrene.

4. The method of claim 1 wherein the precursor comprises Al, Ti and/or Si.

5. The method of claim 1 wherein the material comprising a moisture content of at least 200 ppm has been dried by vacuum or desiccation.

6. The method of claim 1 wherein, before or after the step of exposing, the porous sheet is not exposed to water or a gas that reacts with the one or more elements.

7. A porous separator made by the method of any of the above claims.

8. A method making a battery comprising, following the step of exposing, stacking the porous sheet as a separator with an anode and a cathode.

9. A battery made by the method of claim 8.

10. A porous sheet, comprising:
a porous sheet comprising a material; the porous sheet having two major surfaces and being defined by three mutually-perpendicular directions of thickness, height and width, wherein thickness is the smallest dimension; wherein the material comprises a moisture content of 190 ppm or less, or 170 ppm or less, or in the range of 90 to 190 ppm as measurable by ASTM D7191-10;
the porous sheet comprising:
an upper region defined as the cross-sectional area extending from the upper surface to 10% of the thickness of the porous sheet, and along the width of the porous sheet;
a middle region defined as the cross-sectional area beginning at a point that is 45% of the thickness of the porous sheet from the upper surface, extending to a distance that is 45% of the thickness of the porous sheet from the lower surface, and along the width of the porous sheet;
a lower region defined as the cross-sectional area extending from the lower surface to 10% of the thickness of the porous sheet, and along the width of the porous sheet;
the upper region of the porous sheet comprising one or more elements selected from the group consisting of Zn, Cd, Hg, Al, Ga, In, Si, Ge, Sn and Pb;
wherein the concentration by mass of said one or more elements in the upper region is at least 10% (or at least 20% or in the range of 10 to 70% or 10 to 50%) higher than the concentration of said one or more elements in the middle region and is in the range of 0.01% to 1%, or 0.01 to 0.5%, or 0.01 to 0.1%, or 0.01 to 0.05%.

11. The porous sheet of claim 10 wherein the concentration by mass of said one or more elements in the lower region is at least 10% (or at least 20% or in the range of 10 to 70% or 10 to 50%) higher than the concentration of said one or more elements in the middle region.

12. The porous sheet of claim 10 wherein the concentration by mass of said one or more elements in the upper region is at least 10% (or at least 20% or in the range of 10 to 70% or 10 to 50%) lower than the concentration of said one or more elements in the middle region.

13. The porous sheet of any of claims 10-12 wherein the one or more elements are selected from the group consisting of Al and Si.

14. A battery comprising the porous sheet of any of claims 10-13.
